(19) United States
(12) Patent Application Publication
(10) Pub. No.: US 2025/0323467 A1
(43) Pub. Date: Oct. 16, 2025

(54) OPTICAL MODULE

(71) Applicant: NEC Corporation, Tokyo (JP)

(72) Inventors: Taro KANEKO, Tokyo (JP); Hiroki YASUDA, Tokyo (JP)

(73) Assignee: NEC Corporation, Tokyo (JP)

(21) Appl. No.: 19/089,207

(22) Filed: Mar. 25, 2025

(30) Foreign Application Priority Data
Apr. 16, 2024 (JP) 2024-065844

(51) Int. Cl. H01S 3/00

(52) U.S. Cl. CPC H01S 3/0064

(57) ABSTRACT

An optical module according to the present disclosure includes: a light source configured to output light; an isolator configured to have magnetic force and transmit the light; a housing configured to have a plurality of surfaces and accommodate the light source and the isolator; and a magnetic body configured to be positioned between at least one of the plurality of surfaces of the housing and the isolator.

### INCORPORATION BY REFERENCE

This application is based upon and claims the benefit of priority from Japanese patent application No. 2024-065844, filed on Apr. 16, 2024, the disclosure of which is incorporated herein in its entirety by reference.

### TECHNICAL FIELD

The present disclosure relates to an optical module.

### BACKGROUND ART

Some optical modules, such as a laser unit, include an isolator using a magnet. An example of a method for manufacturing an optical module including an isolator is a technique disclosed in Patent Literature 1.

According to the technique disclosed in Patent Literature 1, an isolator is accommodated in a housing, and a magnet of the isolator is pulled toward an inner surface of the housing by using a holding jig made of a ferromagnetic material. In this state, the isolator is fixed to the housing by laser welding.
[Patent Literature 1] Japanese Patent No. 2503239

### SUMMARY

According to the technique disclosed in Patent Literature 1 described above, during the process of manufacturing the optical module, the isolator is fixed to the inner surface of the housing.

However, in some optical modules, an isolator is mounted at a position away from an inner surface of a housing.

However, the optical module needs to satisfy recent trend of small size and low power consumption. Therefore, even in case where the isolator is mounted at a position away from the inner surface of the housing, a distance between the housing and the isolator is shortened. Therefore, in a case where the housing is made of metal, a magnet of the isolator is pulled toward the housing, which causes a problem that the isolator cannot be mounted in a correct position.

Therefore, an example object of the present disclosure is to provide an optical module in which an isolator can be mounted with high accuracy, in view of the above-described problem.

An example advantage according to the above-described aspect is that an optical module in which an isolator can be mounted with high accuracy is provided.

In an example aspect, an optical module includes:
a light source configured to output light;
an isolator configured to have magnetic force and transmit the light;
a housing configured to have a plurality of surfaces and accommodate the light source and the isolator; and
a magnetic body positioned between at least one of the plurality of surfaces of the housing and the isolator.

### BRIEF DESCRIPTION OF DRAWINGS

The above and other aspects, features, and advantages of the present disclosure will become more apparent from the following description of certain example embodiments when taken in conjunction with the accompanying drawings, in which:

FIG. 1 is a plan view illustrating a configuration example of an optical module according to a related art.

FIG. 2 is a plan view illustrating a configuration example of an isolator.

FIG. 3 is a side view illustrating the configuration example of the isolator.

FIG. 4 is a plan view illustrating a configuration example of an optical module according to the present disclosure.

### EXAMPLE EMBODIMENT

Hereinafter, an example embodiment and a related art of the present disclosure is described with reference to the drawings. Note that the following description and the drawings are omitted and simplified as appropriate for clarity of description. In the following drawings, identical elements are denoted with identical reference signs, and redundant description is omitted as necessary.

Prior to describing the example embodiment of the present disclosure, a related art is described. Note that, an optical module described in the following example embodiment and related art is, for example, a laser unit.

### Related Art

FIG. 1 is a plan view illustrating a configuration example of an optical module 900 according to the related art.

Referring to FIG. 1, the optical module 900 includes a light source 10, an isolator 20, and a housing 30. Note that, the optical module 900 also includes other components such as silicon photonics (SiP) and a booster optical amplifier (BOA), but these other components are omitted in FIG. 1 (the same applies to an optical module 100 described later).

The light source 10 outputs light.

The isolator 20 has magnetic force and transmits the light output from the light source 10. At this time, the isolator 20 transmits the light output from the light source 10 only in an output direction (x-axis plus direction), and blocks the light in an opposite direction (x-axis minus direction) of the output direction. As a result, it is possible to prevent reflected light or the like of the light output from the light source 10 from diffracting toward the light source 10.

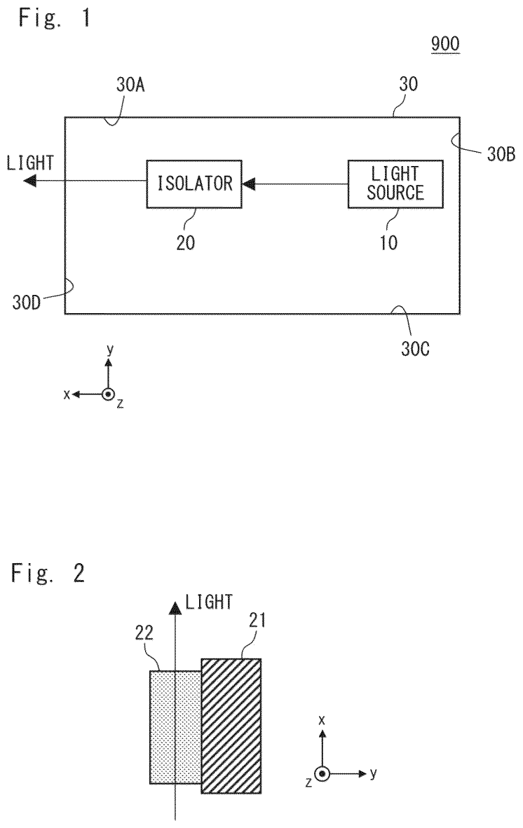

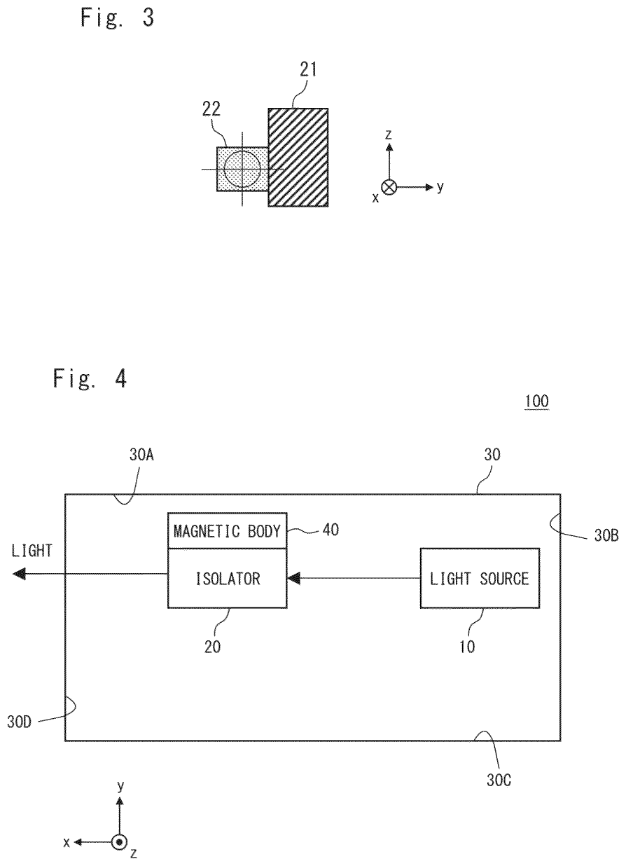

FIGS. 2 and 3 are diagrams illustrating a configuration example of the isolator 20, and FIG. 2 is a plan view and FIG. 3 is a side view.

Referring to FIGS. 2 and 3, the isolator 20 includes a magnet 21 and an optical element 22. Note that, in a case where the isolator 20 illustrated in FIGS. 2 and 3 is incorporated in the optical module 900 illustrated in FIG. 1, the isolator 20 is incorporated in such a way that a main surface (xz-plane) of the magnet 21 faces a later-described surface 30A of the housing 30 (the same applies to the optical module 100 described later).

The magnet 21 has magnetic force.

The optical element 22 transmits the light output from the light source 10.

The optical element 22 includes an element such as a Faraday rotator, and transmits the light output from the light source 10 only in the output direction (x-axis plus direction) by a function of the magnet 21 and the optical element 22, and blocks the light in the opposite direction (x-axis minus direction) of the output direction.

Referring again to FIG. 1, the housing 30 accommodates the light source 10 and the isolator 20. The housing 30 is a rectangular parallelepiped in shape and has four surfaces (inner surfaces) 30A to 30D. However, the housing 30 is not limited to a rectangular parallelepiped shape having four surfaces 30A to 30D, and may have any shape that has a plurality of surfaces (inner surfaces) and is capable of accommodating the light source 10 and the isolator 20.

The housing 30 is made of metal, and is made of, for example, a material containing at least Kovar, and the like.

Here, since the optical module 900 needs to satisfy the recent trend of small size and low power consumption, a distance between the housing 30 and the isolator 20 is shortened. In the example in FIG. 1, the isolator 20 has the shortest distance to the surface 30A of the four surfaces 30A to 30D of the housing 30. The housing 30 is made of metal.

Therefore, in a case where the isolator 20 is mounted, the magnet 21 of the isolator 20 is pulled toward the surface 30A of the housing 30, which causes a problem that the isolator 20 cannot be mounted at a correct position.

An example embodiment of the present disclosure described below solves the above-described problem and enables the isolator 20 to be mounted with high accuracy.

### First Example Embodiment

FIG. 4 is a plan view illustrating a configuration example of an optical module 100 according to the present disclosure.

Referring to FIG. 4, the optical module 100 differs from the optical module 900 in that a magnetic body 40 is added.

The magnetic body 40 is made of, for example, a material containing 40% or more of iron or Kovar, and the like.

The magnetic body 40 is positioned between at least one of four surfaces 30A to 30D of a housing 30 and an isolator 20.

In the example in FIG. 4, the isolator 20 has the shortest distance to the surface 30A of the four surfaces 30A to 30D of the housing 30. Therefore, it is most likely that a magnet 21 of the isolator 20 is pulled toward the surface 30A of the housing 30. Therefore, the magnetic body 40 is positioned between the surface 30A of the housing 30 and the isolator 20. As described above, it is desirable that the magnetic body 40 is at least positioned between the surface 30A having the shortest distance to the isolator 20 among the four surfaces 30A to 30D of the housing 30 and the isolator 20.

According to the first example embodiment, the magnetic body 40 is positioned between the surface 30A of the housing 30 and the isolator 20. Therefore, the isolator 20 is mounted by attaching the magnet 21 to the magnetic body 40. As described above, the isolator 20 is mounted without being pulled toward the surface 30A of the housing 30, and thus can be mounted with high accuracy. In addition, the magnetic body 40 is not pulled toward the surface 30A of the housing 30, and thus can be mounted with high accuracy. Therefore, by mounting the magnetic body 40 with high accuracy, the isolator 20 can be mounted with higher accuracy.

Next, an example of a mounting method of the isolator 20 is described. Herein, it is assumed that the isolator 20 and the magnetic body 40 are to be mounted at positions illustrated in FIG. 4. In the following description, a method of mounting the light source 10 is omitted.

First, between a planned mounting position of the isolator 20 and the surface 30A of the housing 30, the magnetic body 40 is fixed to an inner bottom surface of the housing 30 with an adhesive (first adhesive), or is fixed to any component fixed to the inner bottom surface of the housing 30 with the adhesive (first adhesive). The adhesive may be, for example, an epoxy-based adhesive or an acrylic-based adhesive. At this time, the magnetic body 40 is not pulled toward the surface 30A of the housing 30, and thus can be mounted with high accuracy.

Next, the magnet 21 of the isolator 20 is attached to the magnetic body 40 fixed to the inner bottom surface of the housing 30 or the any component described above. In this state, the magnet 21 of the isolator 20 is fixed to the magnetic body 40 with an adhesive (second adhesive). At this time, the adhesive may be applied to at least one of the magnet 21 or the magnetic body 40 in advance. The adhesive may also be, for example, an epoxy-based adhesive or an acrylic-based adhesive.

As described above, the isolator 20 is fixed to the magnetic body 40 by attaching the magnet 21 to the magnetic body 40. Therefore, the isolator 20 is mounted without being pulled toward the surface 30A of the housing 30, and thus can be mounted with high accuracy.

As described above, according to the first example embodiment, the optical module 100 includes the magnetic body 40 positioned between at least one of the four surfaces 30A to 30D of the housing 30 (the surface 30A in the example in FIG. 4) and the isolator 20. Therefore, the isolator 20 is mounted by attaching the isolator 20 to the magnetic body 40 without being pulled toward the housing 30, and thus can be mounted with high accuracy.

While the present disclosure has been particularly shown and described with reference to example embodiments thereof, the present disclosure is not limited to these example embodiments. It will be understood by those of ordinary skill in the art that various changes in form and details may be made therein without departing from the spirit and scope of the present disclosure as defined by the claims. And each embodiment can be appropriately combined with at least one of embodiments.

Further, each of the drawings or figures is merely an example to illustrate one or more example embodiments. Each figure may not be associated with only one particular example embodiment, but may be associated with one or more other example embodiments. As those of ordinary skill in the art will understand, various features or steps described with reference to any one of the figures can be combined with features or steps illustrated in one or more other figures, for example, to produce example embodiments that are not explicitly illustrated or described. Not all of the features or steps illustrated in any one of the figures to describe an example embodiment are necessarily essential, and some features or steps may be omitted. The order of the steps described in any of the figures may be changed as appropriate.

Further, the whole or part of the example embodiments disclosed above can be described as, but not limited to, the following supplementary notes.

### (Supplementary Note 1)

An optical module including:
a light source configured to output light;
an isolator configured to have magnetic force and transmit the light;
a housing configured to have a plurality of surfaces and accommodate the light source and the isolator; and
a magnetic body configured to be positioned between at least one of the plurality of surfaces of the housing and the isolator.

### (Supplementary Note 2)

The optical module according to supplementary note 1, wherein the magnetic body is at least positioned between a surface having a shortest distance to the isolator among the plurality of surfaces of the housing and the isolator.

### (Supplementary Note 3)

The optical module according to supplementary note 1, wherein the isolator includes:
a magnet configured to have the magnetic force; and
an optical element configured to transmit the light.

### (Supplementary Note 4)

The optical module according to supplementary note 3, wherein
the magnetic body is fixed to an inner bottom surface of the housing with a first adhesive, or is fixed to any component fixed to the inner bottom surface of the housing with the first adhesive, and
the isolator is mounted by attaching the magnet to the magnetic body in a state of being fixed to the inner bottom surface of the housing or the any component.

### (Supplementary Note 5)

The optical module according to supplementary note 4, wherein the first adhesive is an epoxy-based adhesive or an acrylic-based adhesive.

### (Supplementary Note 6)

The optical module according to supplementary note 4, wherein the magnet of the isolator is fixed to the magnetic body with a second adhesive in a state where the magnet is attached to the magnetic body.

### (Supplementary Note 7)

The optical module according to supplementary note 6, wherein the second adhesive is an epoxy-based adhesive or an acrylic-based adhesive.

### (Supplementary Note 8)

The optical module according to supplementary note 1, wherein the magnetic body is made of a material containing 40% or more of Kovar or iron.

### (Supplementary Note 9)

The optical module according to supplementary note 1, wherein the housing is made of a material containing at least Kovar.

### (Supplementary Note 10)

The optical module according to supplementary note 1, wherein the optical module is a laser unit.

What is claimed is:

1. An optical module comprising:
a light source configured to output light;
an isolator configured to have magnetic force and transmit the light;
a housing configured to have a plurality of surfaces and accommodate the light source and the isolator; and
a magnetic body configured to be positioned between at least one of the plurality of surfaces of the housing and the isolator.

2. The optical module according to claim 1, wherein the magnetic body is at least positioned between a surface having a shortest distance to the isolator among the plurality of surfaces of the housing and the isolator.

3. The optical module according to claim 1, wherein the isolator includes:
a magnet configured to have the magnetic force; and
an optical element configured to transmit the light.

4. The optical module according to claim 3, wherein
the magnetic body is fixed to an inner bottom surface of the housing with a first adhesive, or is fixed to any component fixed to the inner bottom surface of the housing with the first adhesive, and
the isolator is mounted by attaching the magnet to the magnetic body in a state of being fixed to the inner bottom surface of the housing or the any component.

5. The optical module according to claim 4, wherein the first adhesive is an epoxy-based adhesive or an acrylic-based adhesive.

6. The optical module according to claim 4, wherein the magnet of the isolator is fixed to the magnetic body with a second adhesive in a state where the magnet is attached to the magnetic body.

7. The optical module according to claim 6, wherein the second adhesive is an epoxy-based adhesive or an acrylic-based adhesive.

8. The optical module according to claim 1, wherein the magnetic body is made of a material containing 40% or more of Kovar or iron.

9. The optical module according to claim 1, wherein the housing is made of a material containing at least Kovar.

10. The optical module according to claim 1, wherein the optical module is a laser unit.
